(19) United States
(12) Patent Application Publication
(10) Pub. No.: US 2025/0372567 A1
(43) Pub. Date: Dec. 4, 2025

(54) SEMICONDUCTOR DEVICE AND MANUFACTURING METHOD THEREOF

(71) Applicant: Kioxia Corporation, Minato-ku (JP)

(72) Inventor: Satoru ITAKURA, Machida Tokyo (JP)

(73) Assignee: Kioxia Corporation, Minato-ku (JP)

(21) Appl. No.: 19/010,660

(22) Filed: Jan. 6, 2025

(30) Foreign Application Priority Data
Jun. 4, 2024 (JP) 2024-090635

(51) Int. Cl. H01L 23/00

(52) U.S. Cl. CPC H01L 24/48; H01L 24/06; H01L 24/45; H01L 24/49; H01L 2224/06131; H01L 2224/06135; H01L 2224/45005; H01L 2224/48105; H01L 2224/48228; H01L 2224/48451; H01L 2224/48465; H01L 2224/48471; H01L 2224/48482; H01L 2224/49174; H01L 2224/49429; H01L 2924/37001; H01L 2924/3861

(57) ABSTRACT

A semiconductor device according to the present embodiment includes a first pad, a second pad, a third pad, a first bonding wire joined to the first pad, a second bonding wire provided on the second pad with a second stud bump in between, and a third bonding wire joined to the third pad. The second pad is positioned between the first and third pads. The second bonding wire includes a second ball portion and a second wire portion, the second ball portion being joined to the second stud bump, the second wire portion extending from the second ball portion.

### CROSS REFERENCE TO RELATED APPLICATIONS

This application is based upon and claims the benefit of priority from the prior Japanese Patent Application No. 2024-090635, filed on Jun. 4, 2024, the entire contents of which are incorporated herein by reference.

### FIELD

The embodiments of the present invention relate to a semiconductor device and a manufacturing method thereof.

### BACKGROUND

In a semiconductor packaging process, for example, wires are formed on a plurality of pads provided on a semiconductor chip by wire bonding in some cases. In a case where the pad pitch is narrow, a capillary potentially contacts an already formed wire. Deformation occurs to the wire contacted by the capillary, which can lead to a deterioration in yield.

### BRIEF DESCRIPTION OF THE DRAWINGS

FIG. 1 is a cross sectional view illustrating an example of the configuration of a semiconductor device according to a first embodiment;

FIG. 2 is a top view illustrating an example of the configuration of a semiconductor chip according to the first embodiment;

FIG. 3 is a perspective view illustrating an example of the configuration of a connector between a bonding wire and a pad according to the first embodiment;

FIG. 4 is a perspective view illustrating an example of the configuration of a bonding wire according to the first embodiment;

FIG. 5 is a cross sectional view illustrating an example of the configuration of a connector between a bonding wire and a pad according to the first embodiment;

FIG. 6 is a perspective view illustrating an example of the configuration of a connector between a bonding wire and a pad according to a comparative example;

FIG. 7 is a cross sectional view illustrating an example of the configuration of a connector between a bonding wire and a pad according to the comparative example;

FIG. 8 is a cross sectional view illustrating an example of simulation parameters according to the comparative example;

FIG. 9 is a cross sectional view illustrating an example of simulation parameters according to the first embodiment;

FIG. 10 is a graph illustrating examples of a wire height according to the first embodiment and the comparative example;

FIG. 11 is a table listing examples of a magnification according to the first embodiment;

FIG. 12 is a cross sectional view illustrating an example of the configuration of a semiconductor device according to a second embodiment;

FIG. 13 is a top view illustrating an example of the configuration of a semiconductor chip according to a third embodiment;

FIG. 14 is a top view illustrating an example of the configuration of a semiconductor chip according to a modification of the third embodiment;

FIG. 15 is a cross sectional view illustrating an example of the configuration of a bonding wire according to the modification of the third embodiment;

FIG. 16 is a cross sectional view illustrating an example of the configuration of a semiconductor device according to a fourth embodiment;

FIG. 17 is a cross sectional view illustrating an example of the configuration of a semiconductor device according to a fifth embodiment; and

FIG. 18 is a cross sectional view illustrating an example of the configuration of a bonding wire according to a sixth embodiment.

### DETAILED DESCRIPTION

Embodiments will now be explained with reference to the accompanying drawings. The present invention is not limited to the embodiments. It should be noted that the drawings are schematic or conceptual, and the relationship between the thickness and the width in each element and the ratio among the dimensions of elements do not necessarily match the actual ones. Even if two or more drawings show the same portion, the dimensions and the ratio of the portion may differ in each drawing. In the present specification and the drawings, elements identical to those described in the foregoing drawings are denoted by like reference characters and detailed explanations thereof are omitted as appropriate.

A semiconductor device according to the present embodiment includes a first pad, a second pad, a third pad, a first bonding wire joined to the first pad, a second bonding wire provided on the second pad with a second stud bump in between, and a third bonding wire joined to the third pad. The second pad is positioned between the first and third pads. The second bonding wire includes a second ball portion and a second wire portion, the second ball portion being joined to the second stud bump, the second wire portion extending from the second ball portion.

### First Embodiment

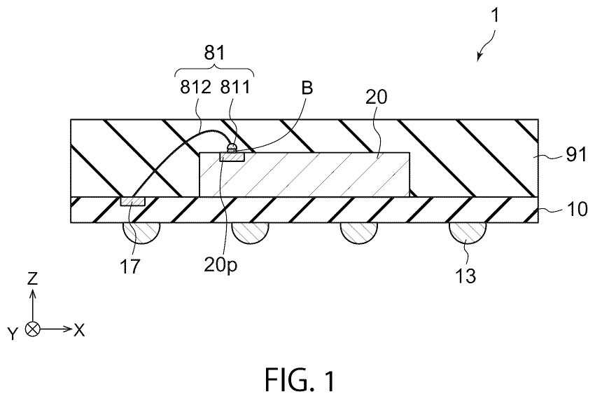

FIG. 1 is a cross sectional view illustrating an example of the configuration of a semiconductor device 1 according to a first embodiment. The semiconductor device 1 includes a wiring substrate 10, a semiconductor chip 20, a bonding wire 81, and a sealing resin 91. The semiconductor device 1 is, for example, a packaged NAND type flash memory.

FIG. 1 illustrates an X direction and a Y direction parallel to a front surface of a substrate (wiring substrate 10) and orthogonal to each other, and a Z direction orthogonal to the front surface of the substrate (wiring substrate 10). In the present specification, the positive Z direction is an upward direction, and the negative Z direction is a downward direction. The negative Z direction may or may not be aligned with the gravity direction.

The wiring substrate 10 may be a printed circuit board or interposer including a wiring layer (not illustrated) and an insulating layer (not illustrated). A low resistance metal such as copper (Cu), nickel (Ni) or alloy thereof is used as the wiring layer. An insulating material such as glass epoxy resin is used as the insulating layer. The wiring substrate 10 may include a multi-layer wiring structure formed by stacking a plurality of wiring layers and a plurality of insulating layers. The wiring substrate 10 may include a penetration electrode penetrating through front and back surfaces thereof like an interposer.

A solder resist layer provided on the wiring layer is provided on the front surface of the wiring substrate 10. The solder resist layer is also used for the insulating layer for protecting the wiring layer and preventing a short-circuit defect. A pad 17 is provided on the front surface of the wiring substrate 10. The pad 17 is the wiring layer exposed from the solder resist layer. The pad 17 is electrically connected to the semiconductor chip 20. The pad 17 contains, for example, aluminum (Al). However, the pad 17 may be, for example, a gold (Au) plated electrode.

A solder resist layer provided on the wiring layer is provided on the back surface of the wiring substrate 10. Metal bumps 13 are provided on the wiring layer exposed from the solder resist layer. The metal bumps 13 are provided to electrically connect a non-illustrated other component to the wiring substrate 10.

The semiconductor chip 20 is, for example, a memory chip including a NAND type flash memory. The semiconductor chip 20 is provided with a semiconductor element (not illustrated) on its front surface (upper surface). The semiconductor element may be, for example, a memory cell array and its peripheral circuit (complementary metal oxide semiconductor (CMOS) circuit). The memory cell array may be a stereoscopic memory cell array in which a plurality of memory cells are three-dimensionally disposed. In the diagram, the semiconductor chip 20 as one memory chip is provided. However, two or more semiconductor chips may be stacked.

The bonding wire 81 is connected to the wiring substrate 10 and an optional pad 20p of the semiconductor chip 20. The bonding wire 81 is, for example, a gold (Au) wire.

The bonding wire 81 electrically connects the semiconductor chip 20 and the wiring substrate 10. More specifically, the bonding wire 81 electrically connects the semiconductor chip 20 and the pad 17.

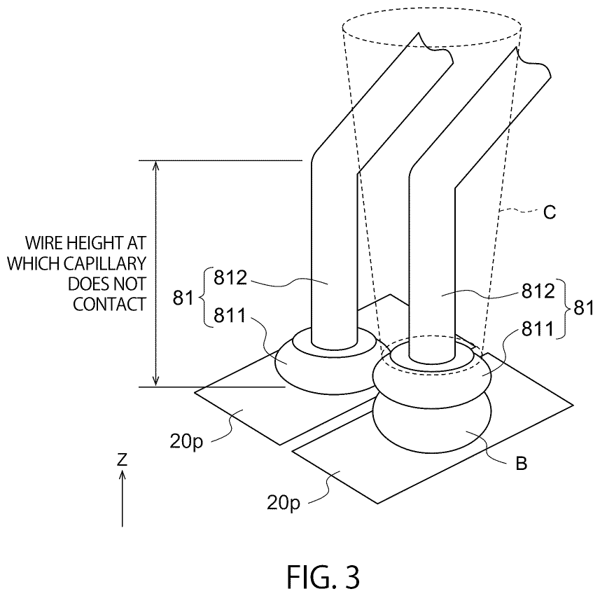

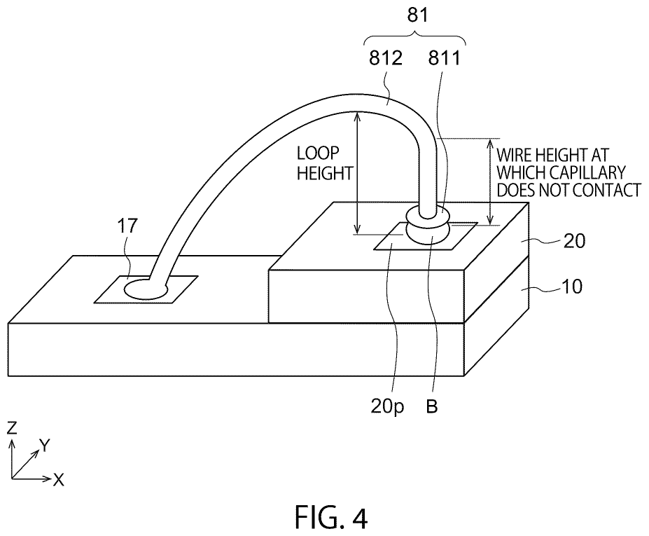

In the example illustrated in FIG. 1, the bonding wire 81 includes a ball portion 811 at an end part of the semiconductor chip 20 on the pad 20p side. Accordingly, the bonding wire 81 is formed by forward bonding. Details of the bonding wire 81 will be described later with reference to FIGS. 3 and 4.

The sealing resin 91 seals the semiconductor chip 20, the bonding wire 81, and the like. Accordingly, in the semiconductor device 1, the semiconductor chip 20 is constituted as one semiconductor package on the wiring substrate 10.

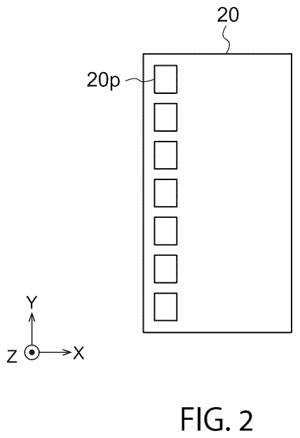

FIG. 2 is a top view illustrating an example of the configuration of the semiconductor chip 20 according to the first embodiment. FIG. 2 is a diagram of the semiconductor chip 20 when viewed in the Z direction.

The semiconductor chip 20 is substantially quadrilateral when viewed 10 in the Z direction.

A plurality of pads 20p are provided on the semiconductor chip 20, for example, along one of the two long sides of the semiconductor chip 20. Specifically, the plurality of pads 20p are arranged, for example, in the Y 15 direction. In the present specification, “arranged in the Y direction” means that a plurality of adjacent pads 20p at least partially overlap in, for example, the X direction intersecting the Y direction. The number of pads 20p is not limited to the example illustrated in FIG. 2.

FIG. 3 is a perspective view illustrating an example of the configuration of a connector between the bonding wire 81 and the corresponding pad 20p according to the first embodiment. FIG. 3 is an enlarged perspective view of the vicinity of the connector between the bonding wire 81 and the pad 20p.

Two adjacent pads 20p are provided with a pad pitch such that a capillary C contacts an adjacent bonding wire 81 when bonding is consecutively performed. FIG. 3 also illustrates the position of the capillary C during bonding.

The semiconductor device 1 further includes a bump B.

The bump B is provided on one of two adjacent pads 20p. The bump B is provided between the pad 20p and the bonding wire 81. The material of the bump B is the same as the material of the bonding wire 81, for example.

Two bonding wires 81 illustrated in FIG. 3 are provided on the other of the two adjacent pads 20p and the bump B. The bonding wire 81 provided on the other of the two adjacent pads 20p is an example of a first wire. The bonding wire 81 provided on the bump B is an example of a

second wire. Each bonding wire 81 includes the ball portion 811, a wire portion

812, and a wedge portion (not illustrated). The ball portion 811 is joined to the other of the two adjacent pads 20p or the bump B. The ball portion 811 on the pad 20p on which the bump B is not provided is joined to the pad 20p. The ball portion 811 above the pad 20p on which the bump B is provided is joined to the bump B.

Each wire portion 812 extends from the corresponding ball portion 811. As illustrated in FIG. 3, for example, the wire portion 812 extends substantially vertically upward from the ball portion 811 and inclines toward the pad 17.

As described above, the bonding wires 81 are formed by forward bonding.

During forward bonding, first, first bonding (ball bonding) is performed on a pad 20p of the semiconductor chip 20 or the bump B to form a ball portion 811. Subsequently, the capillary C is moved so that a wire portion 812 of a desired shape is obtained. Subsequently, second bonding (wedge bonding) is performed on the pad 17 of the wiring substrate 10 to form a wedge portion that is an end part opposite the ball portion 811.

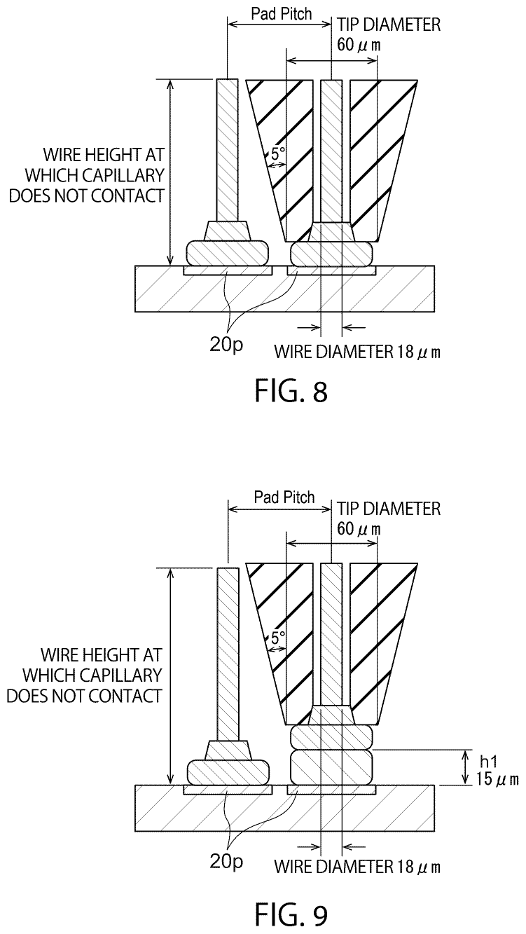

A “wire height at which the capillary C does not contact” refers to the highest point of a bonding wire 81, which vertically extends in the Z direction from the lower end of the bonding wire 81 (length of the bonding wire 81 that appears in a cross sectional view (refer to FIG. 8) at a pad 20p) when the capillary C descends to form an adjacent bonding wire 81.

FIG. 4 is a perspective view illustrating an example of the configuration of a bonding wire 81 according to the first embodiment. FIG. 4 illustrates a bonding wire 81 provided on the bump B and its vicinity.

The wedge portion of the bonding wire 81 is formed on the pad 17.

“Loop height” refers to the height from a pad 20p to the apex of the bonding wire 81.

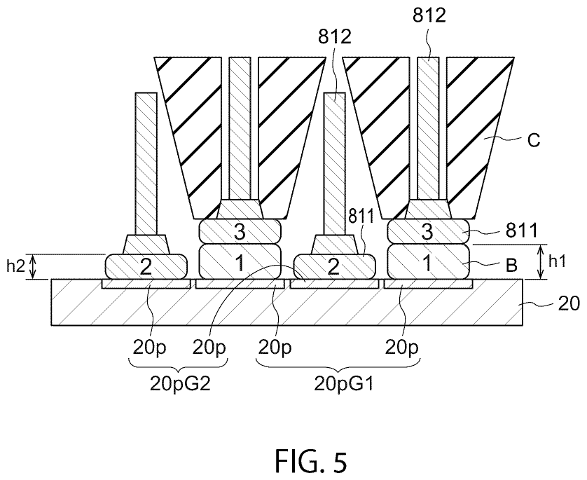

FIG. 5 is a cross sectional view illustrating an example of the configuration of a connector between a bonding wire 81 and a pad 20p according to the first embodiment. FIG. 5 is a cross sectional view of the connector illustrated in FIG. 3.

Numbers written in ball portions 811 and bumps B in FIG. 5 indicate orders (processing groups) of consecutive bonding processing with the capillary C. The orders of consecutive bonding processing within the same processing group are optional. A height h1 illustrated in FIG. 5 is the height of each bump B from the semiconductor chip 20. A height h2 is the height of each ball portion 811 from the semiconductor chip 20.

First in processing group 1, bumps B are formed on pads 20p (pad group 20pG1) that are each one of two adjacent pads 20p among a plurality of pads 20p. The bumps B are, for example, stud bumps formed by wire bonding. As illustrated in FIG. 5, the bumps B are formed on every other pads 20p among a plurality of pads 20p arranged in a first direction (for example, the Y direction illustrated in FIG. 2) that is the right-left direction of the sheet of FIG. 5. In other words, pads 20p on which the bumps B are formed and pads 20p on which the bumps B are not formed are alternately arranged in the first direction.

In a case where pads 20p are provided in two or more lines, the first direction may include the X direction.

Subsequently in processing group 2, bonding wires 81 are formed on pads 20p (pad group 20pG2) that are each the other of the two adjacent pads 20p. The ball portions 811 are provided on the pads 20p by ball bonding.

Subsequently in processing group 3, bonding wires 81 are formed on the bumps B. The ball portions 811 are provided on the bumps B by ball bonding. FIG. 5 also illustrates the position of the capillary C during ball bonding of processing group 3.

As illustrated in FIG. 5, in processing group 3, the bonding wires 81 are formed at positions higher than positions where the bonding wires 81 are formed in processing group 2 by the height h1 of the bumps B. Accordingly, the clearance (gap) between each bonding wires 81 already formed in processing group 2 and the capillary C in processing group 3 is increased. As a result, it is possible to prevent deformation of bonding wires 81 due to contact with the capillary C, thereby preventing a deterioration in yield.

As described above, according to the first embodiment, bumps B are provided on pads 20p (pad group 20pG1) that are each one of two adjacent pads 20p. A plurality of bonding wires 81 are provided on pads 20p (pad group 20pG2) that are each the other of the two adjacent pads 20p and the bumps B. Accordingly, the clearance between each already formed wire portion 812 and the capillary C is increased. Specifically, each bump B is provided on a pad 20p of the pad group 20pG1, which is positioned between two pads 20p of the pad group 20pG2. In other words, each bump B is provided on a pad 20p of the pad group 20pG1, which at least partially overlaps two adjacent pads 20p of the pad group 20pG2 in the X direction, for example. As a result, the bonding wires 81 can be more appropriately formed even with a narrow pad pitch.

The bonding wires 81 and the bumps B are not limited to gold (Au) but may contain silver (Ag) or copper (Cu).

The material of the bumps B may be different from the material of bonding wires 81 provided on the bumps B. For example, the material of the bumps B may be changed to suppress alloying between the pads 20p and the bumps B.

The semiconductor device 1 may further include a controller chip configured to control a memory chip.

In the example illustrated in FIG. 5, the bumps B are higher than the ball portions 811, but the present invention is not limited thereto. The heights of the bumps B can be changed with formation conditions. Examples of formation condition parameters include the size of a ball at the tip of the capillary C before the first bonding (ball bonding), and a load during the first bonding.

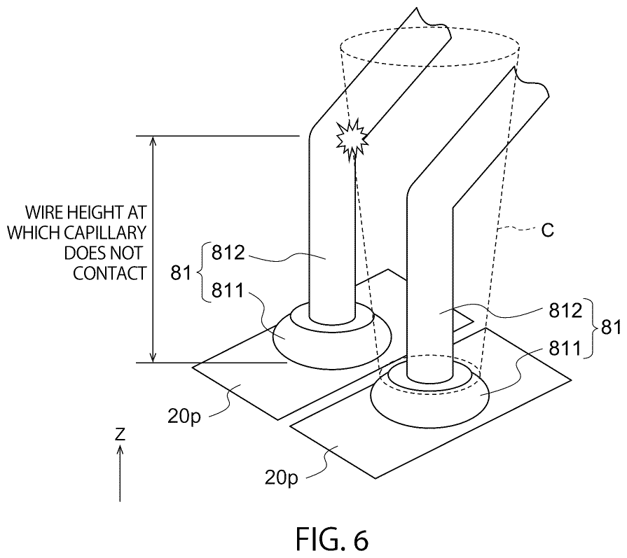

FIG. 6 is a perspective view illustrating an example of the configuration of a connector between a bonding wire 81 and a pad 20p according to a comparative example. The comparative example is different from the first embodiment in that no bumps B are provided.

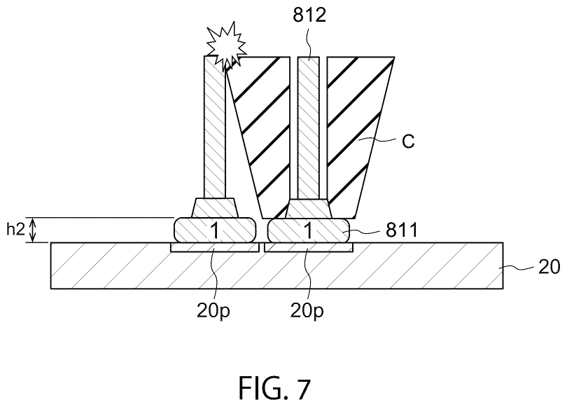

FIG. 7 is a cross sectional view illustrating an example of the configuration of a connector between a bonding wire 81 and a pad 20p according to the comparative example. FIG. 7 is a cross sectional view of the connector illustrated in FIG. 6.

Numbers written in ball portions 811 in FIG. 7 indicate orders (processing groups) of consecutive bonding processing with the capillary C. The orders of consecutive bonding processing within the same processing group are optional.

In processing group 1, a bonding wire 81 is formed on a pad 20p on the left side illustrated in FIG. 7, and thereafter, another bonding wire 81 is formed on a pad 20p on the right side.

However, in a case where the pad pitch of pads 20p is narrow, the capillary C potentially contacts an already formed bonding wire 81. Deformation occurs to the bonding wire 81 contacted by the capillary C, which can lead to a deterioration in yield.

However, in the first embodiment, since the bumps B are provided, the clearance between each already formed wire portion 812 and the capillary C is increased. As a result, the bonding wires 81 can be more appropriately formed even with a narrow pad pitch.

Simulation results of wire height comparison between the first embodiment and the comparative example will be described below.

FIG. 8 is a cross sectional view illustrating an example of simulation parameters according to the comparative example. FIG. 9 is a cross sectional view illustrating an example of simulation parameters according to the first embodiment.

The pad pitch is the distance between the centers of adjacent pads 20p. The wire diameter of each wire portion 812 is, for example, 18 μm. The tip diameter of the capillary C is, for example, 60 μm. The taper angle of the tip of the capillary C is, for example, 5°. The height h1 of each bump B according to the first embodiment is, for example, 15 μm.

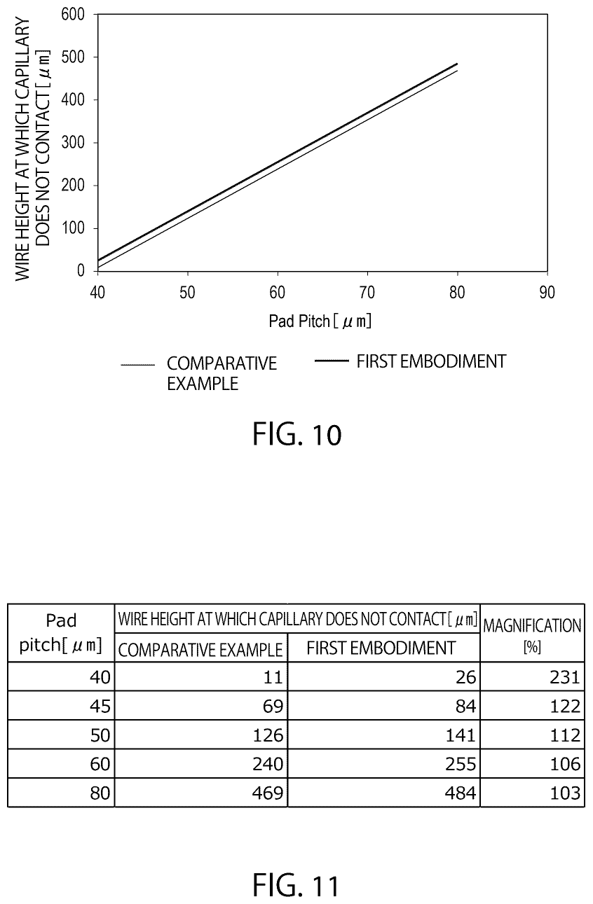

FIG. 10 is a graph illustrating examples of the wire height according to the first embodiment and the comparative example. The vertical axis of the graph represents the wire height (μm) at which the capillary C does not contact. The horizontal axis of the graph represents the pad pitch (μm).

As illustrated in FIG. 10, the wire height at which the capillary C does not contact and the pad pitch have a proportional relation. Specifically, the wire height at which the capillary C does not contact decreases as the pad pitch decreases.

At the same pad pitch, the wire height at which the capillary C does not contact according to the first embodiment is higher than the wire height at which the capillary C does not contact according to the comparative example.

FIG. 11 is a table listing examples of a magnification according to the first embodiment. The table illustrated in FIG. 11 is a table with values extracted from simulation results illustrated in FIG. 10. The magnification (%) is the ratio of the wire height at which the capillary C does not contact according to the first embodiment to the wire height at which the capillary C does not contact according to the comparative example.

In FIG. 11, simulation results with the pad pitch in the range of 40 μm to 80 μm are listed as an example. At any pad pitch, the wire height at which the capillary C does not contact according to the first embodiment is higher than the wire height at which the capillary C does not contact according to the comparative example by 15 μm, which is the height of the bumps B. The magnification is larger as the pad pitch is smaller.

Values such as the pad pitch and the height of the bumps B described above with reference to FIGS. 8 to 11 are not limited to the examples illustrated in FIGS. 8 to 11.

### Second Embodiment

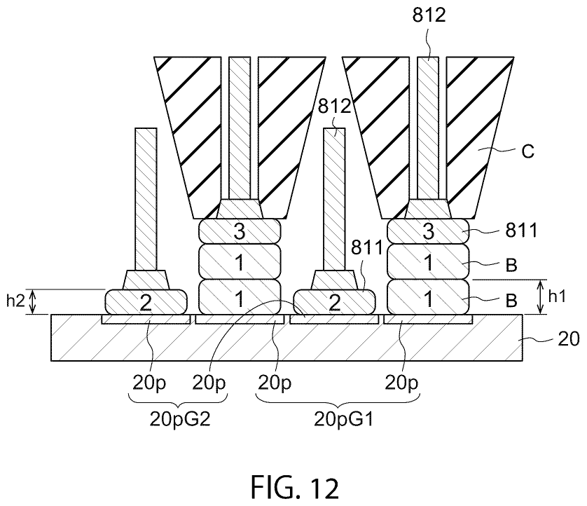

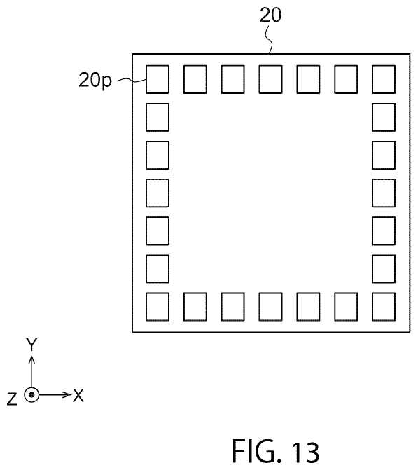

FIG. 12 is a cross sectional view illustrating an example of the configuration of the semiconductor device 1 according to a second embodiment. The second embodiment is different from the first embodiment in that a plurality of stacked layers of bumps B are provided.

The semiconductor device 1 further includes a plurality of stacked layers of bumps B on a pad 20p, in other words, between a pad 20p and a ball portion 811. A bonding wire 81 is provided on the uppermost bump B. Accordingly, the height of the ball portion 811 is adjusted. Moreover, the clearance between each already formed wire portion 812 and the capillary C is further increased.

In the example illustrated in FIG. 12, the bumps B are stacked in two layers. However, the bumps B may be stacked in three or more layers.

As in the second embodiment, a plurality of stacked layers of bumps B may be provided. With the semiconductor device 1 according to the second embodiment, it is possible to obtain the same effects as in the first embodiment.

### Third Embodiment

FIG. 13 is a top view illustrating an example of the configuration of the semiconductor chip 20 according to a third embodiment. The third embodiment is different from the first embodiment in that the semiconductor chip 20 is a logic chip.

The semiconductor chip 20 is, for example, a controller chip (logic chip) configured to control a memory chip. The semiconductor chip 20 is provided with a semiconductor element (not illustrated) on its front surface (upper surface). The semiconductor element may be, for example, a complementary metal oxide semiconductor (CMOS) circuit constituting a controller.

The semiconductor chip 20 is substantially square when viewed in the Z direction.

A plurality of pads 20p are provided on the semiconductor chip 20, for example, along the four sides of the semiconductor chip 20. Specifically, the plurality of pads 20p are arranged, for example, in the Y and X directions. In the present specification, “arranged in the X direction” means that a plurality of adjacent pads 20p at least partially overlap in, for example, the Y direction intersecting the X direction. The number of pads 20p is not limited to the example illustrated in FIG. 13.

As in the third embodiment, the semiconductor chip 20 may be a logic chip. With the semiconductor device 1 according to the third embodiment, it is possible to obtain the same effects as in the first embodiment.

### Modification of Third Embodiment

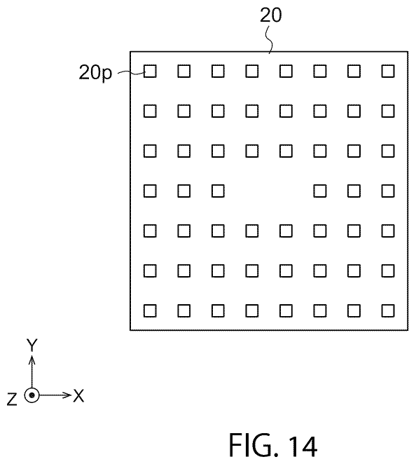

FIG. 14 is a top view illustrating an example of the configuration of the semiconductor chip 20 according to a modification of the third embodiment. The modification of the third embodiment is different from the third embodiment in that pads 20p are provided in a plurality of lines.

A plurality of pads 20p may be provided in three lines in a lattice shape. The pads 20p may be provided in two lines or in four or more lines. Alternatively, the pads 20p may be provided in a staggered shape or the like.

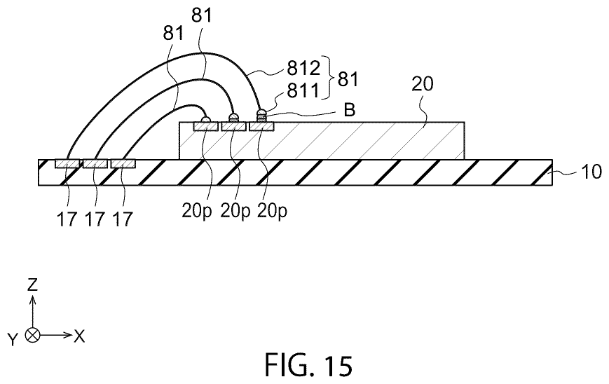

FIG. 15 is a cross sectional view illustrating an example of the configuration of a bonding wire 81 according to the modification of the third embodiment. FIG. 15 illustrates some pads 17 and 20p, bonding wires 81, and their nearby components. In FIG. 15, the pads 20p are provided in three lines.

In a case where the pads 20p are provided in two or more lines, a bonding wire 81 connected to a pad 20p provided on the inner side of the semiconductor chip 20 needs to be provided over a bonding wire 81 connected to a pad 20p provided on the outer side of the semiconductor chip 20 as illustrated in FIG. 15. In other words, the loop height of a bonding wire 81 connected to a pad 20p provided on the inner side of the semiconductor chip 20 needs to be higher than the loop height of a bonding wire 81 connected to a pad 20p provided on the outer side of the semiconductor chip 20. Thus, it is preferable that, as the position moves further on the inner side of the semiconductor chip 20, the height of each bump B increases or a plurality of bumps B are stacked as in the second embodiment. In other words, as the position moves further on the inner side of the semiconductor chip 20, the height of each bump B on a pad 20p increases. The height of each bump B is the height from the wiring substrate 10 to the upper surface of the bump B. In a case where a plurality of bumps B are stacked, the height of the bumps B is the height from the wiring substrate 10 to the upper surface of the uppermost layer of the plurality of bumps B.

The bumps B are provided such that, among a plurality of pads 20p the wire portion 812 of which extends in a second direction (the negative X direction in FIG. 15) on an end part side opposite the ball portion 811, the height of a ball portion 811 provided above a pad 20p provided on a side opposite the second direction is higher than the height of a ball portion 811 provided above a pad 20p provided on the second direction side.

The plurality of pads 17 illustrated in FIG. 15 do not have the same X coordinate. The plurality of pads 17 are adjacently disposed at different positions in a direction (X direction) with respect to the plurality of pads 20p.

Pads on the inner side are connected to each other, and pads on the outer side are connected to each other. Pads 20p on a side closer to the pads 17 among the plurality of pads 20p are connected to pads 17 on a side closer to the pads 20p among the plurality of pads 17 through bonding wires 81. Pads 20p on a side farther from the pads 17 among the plurality of pads 20p are connected to pads 17 on a side farther from the pads 20p among the plurality of pads 17 through bonding wires 81.

As in the modification of the third embodiment, pads 20p may be provided in a plurality of lines. With the semiconductor device 1 according to the modification of the third embodiment, it is possible to obtain the same effects as in the third embodiment. The semiconductor device 1 according to the modification of the third embodiment may be combined with the first and second embodiments. In other words, the pads 20p of the semiconductor chip 20 as a memory chip may be provided in a plurality of lines.

### Fourth Embodiment

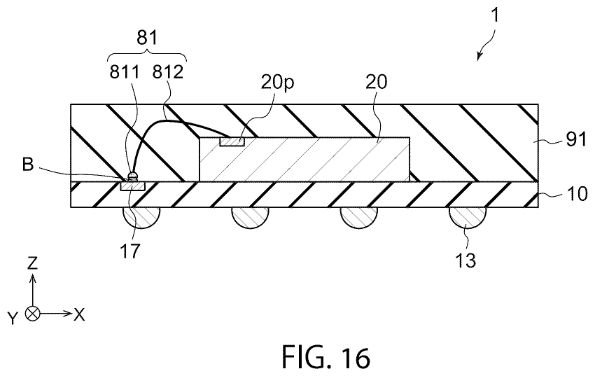

FIG. 16 is a cross sectional view illustrating an example of the configuration of the semiconductor device 1 according to a fourth embodiment. The fourth embodiment is different from the first embodiment in that bonding wires 81 are formed by reverse bonding.

In the example illustrated in FIG. 16, each bonding wire 81 includes a ball portion 811 at an end part of the wiring substrate 10 on the pad 17 side.

A non-illustrated bump B is provided on one of two adjacent pads 17. The bump B is provided between the pad 17 and a bonding wire 81.

During reverse bonding, first, the first bonding (ball bonding) is performed on the pad 17 of the wiring substrate 10 or the bump B to form a ball portion 811. Subsequently, the capillary C is moved so that a wire portion 812 of a desired shape is obtained. Subsequently, the second bonding (wedge bonding) is performed on a pad 20p of the semiconductor chip 20 to form a wedge portion that is an end part opposite the ball portion 811.

In the case of reverse bonding, the wire portion 812 often extends higher above the pad 17 joined to the ball portion 811 than the case of forward bonding. As a result, the capillary C is more likely to contact the bonding wire 81. Thus, with the same pad pitch, bumps B are more preferably provided in the fourth embodiment than in the case of forward bonding (first embodiment).

A plurality of bonding wires 81 may be formed by forward bonding and reverse bonding in mixture.

As in the fourth embodiment, bonding wires 81 may be formed by reverse bonding. With the semiconductor device 1 according to the fourth embodiment, it is possible to obtain the same effects as in the first embodiment. The semiconductor device 1 according to the fourth embodiment may be combined with the second and third embodiments. Specifically, bonding wires 81 may be formed by reverse bonding in the second and third embodiments.

### Fifth Embodiment

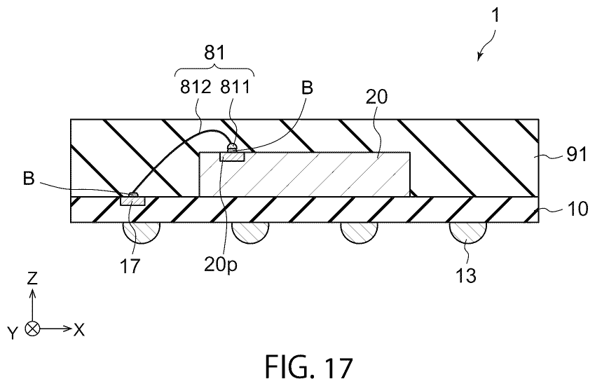

FIG. 17 is a cross sectional view illustrating an example of the configuration of the semiconductor device 1 according to a fifth embodiment. The fifth embodiment is different from the first embodiment in that bumps B are provided on pads 17 as well.

A bump B is also provided between each pad 17 and the wedge portion of the corresponding bonding wire 81. Accordingly, during the second bonding as well, the clearance between each already formed wire portion 812 and the capillary C is increased. As a result, the bonding wires 81 can be more appropriately formed even with a narrow pad pitch.

As in the fifth embodiment, bumps B may be provided on pads 17 as well. With the semiconductor device 1 according to the fifth embodiment, it is possible to obtain the same effects as in the first embodiment.

### Sixth Embodiment

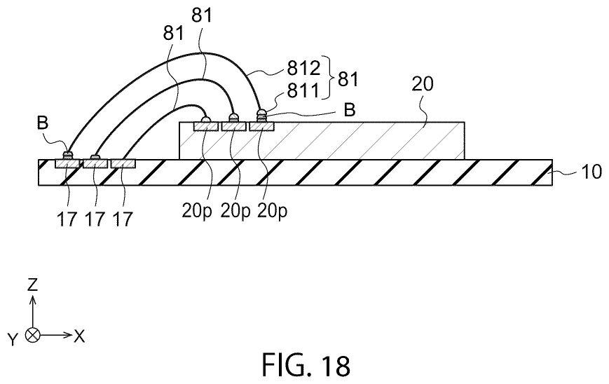

FIG. 18 is a cross sectional view illustrating an example of the configuration of a bonding wire 81 according to a sixth embodiment. The sixth embodiment is different from the fifth embodiment in that pads 20p are provided in a plurality of lines. Specifically, the sixth embodiment is a combination of the modification of the third embodiment and the fifth embodiment.

Similarly to the bumps B described above in the modification of the third embodiment, bumps B on pads 17 may be adjusted in height. Specifically, the bumps B on the pads 17 become higher as the position moves farther away from the semiconductor chip 20.

The bumps B on the pads 17 are provided such that, among a plurality of pads 17 the wire portion 812 of which extends in a third direction (the positive X direction in FIG. 15) on the ball portion 811 side, the height of a wedge portion provided above a pad 17 provided on a side opposite the third direction is higher than the height of a wedge portion provided above a pad 17 provided on the third direction side.

As in the sixth embodiment, pads 20p may be provided in a plurality of lines. With the semiconductor device 1 according to the sixth embodiment, it is possible to obtain the same effects as in the fifth embodiment.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

1. A semiconductor device comprising:
a first pad;
a second pad;
a third pad;
a first bonding wire joined to the first pad;
a second bonding wire provided on the second pad with a second stud bump interposed in between; and
a third bonding wire joined to the third pad, wherein
the second pad is positioned between the first pad and the third pad, and
the second bonding wire includes a second ball portion and a second wire portion, the second ball portion being joined to the second stud bump, the second wire portion extending from the second ball portion.

2. The semiconductor device according to claim 1, wherein
the first bonding wire includes a first ball portion and a first wire portion, the first ball portion being joined to the first pad, the first wire portion extending from the first ball portion, and
the third bonding wire includes a third ball portion and a third wire portion, the third ball portion being joined to the third pad, the third wire portion extending from the third ball portion.

3. The semiconductor device according to claim 1, wherein
the second stud bump includes a plurality of stud bumps, and
the second ball portion is joined to an uppermost layer of the plurality of stud bumps.

4. The semiconductor device according to claim 1, further comprising:
a fourth pad; and
a fourth bonding wire provided on the fourth pad with a fourth stud bump interposed in between, wherein
the first, second, and third pads are arranged in a first direction,
the second bonding wire extends in a second direction that intersects the first direction,
the fourth pad is provided relative to the second pad in a third direction different from the first direction and the second direction,
the fourth bonding wire includes a fourth ball portion and a fourth wire portion, the fourth ball portion being joined to the fourth stud bump, the fourth wire portion extending from the fourth ball portion, and
a height of the fourth ball portion is higher than a height of the second ball portion.

5. The semiconductor device according to claim 1, further comprising:
a substrate;
a semiconductor chip provided on the substrate and electrically connected to the substrate through the first bonding wire, the second bonding wire, or the third bonding wire; and
a fifth pad, wherein
the first, second, and third pads are provided on one of the substrate and the semiconductor chip, and
the fifth pad is provided on the other of the substrate and the semiconductor chip.

6. The semiconductor device according to claim 5, further comprising a sixth pad provided on the other of the substrate and the semiconductor chip, wherein
the first, second, and third pads are arranged in a first direction, and
the fifth and sixth pads are disposed at positions different from each other in a second direction that intersects the first direction.

7. The semiconductor device according to claim 5, further comprising:
a fourth pad provided on one of the substrate and the semiconductor chip; and
a seventh pad provided on the other of the substrate and the semiconductor chip, wherein
the first, second, and third pads are arranged in a first direction,
the second bonding wire extends in a second direction that intersects the first direction,
the fourth pad is provided relative to the second pad in a third direction different from the first direction and the second direction,
the seventh pad is provided relative to the fifth pad in the second direction,
any one of the first, second, and third pads is electrically connected to the fifth pad, and
the fourth pad is electrically connected to the seventh pad.

8. The semiconductor device according to claim 5, wherein the fifth pad is joined to the second wire portion through a fifth stud bump.

9. The semiconductor device according to claim 5, wherein
the first, second, and third pads are provided on the semiconductor chip, and
the fifth pad is provided on the substrate.

10. The semiconductor device according to claim 5, wherein
the first, second, and third pads are provided on the substrate, and
the fifth pad is provided on the semiconductor chip.

11. The semiconductor device according to claim 1, wherein a material of the second stud bump is different from a material of the second bonding wire provided on the second stud bump.

12. A semiconductor device comprising:
a first pad provided on a first surface;
a second pad provided on the first surface;
a third pad provided on the first surface;
a fourth pad provided on a second surface;
a first bonding wire joined to the first pad;
a second bonding wire with one end provided on the second pad with a second stud bump in between; and
a third bonding wire joined to the third pad, wherein
the second pad is positioned between the first pad and the third pad,
the second bonding wire includes a second ball portion and a second wire portion, the second ball portion being joined to the second stud bump, the second wire portion extending from the second ball portion, and
the fourth pad is joined to the second wire portion through a fourth stud bump.

13. The semiconductor device according to claim 12, further comprising:
a semiconductor chip having the first surface; and
a substrate having the second surface.

14. The semiconductor device according to claim 12, further comprising:
a substrate having the first surface; and
a semiconductor chip having the second surface.

15. The semiconductor device according to claim 12, wherein
the first bonding wire includes a first ball portion and a first wire portion, the first ball portion being joined to the first pad, the first wire portion extending from the first ball portion, and
the third bonding wire includes a third ball portion and a third wire portion, the third ball portion being joined to the third pad, the third wire portion extending from the third ball portion.

16. The semiconductor device according to claim 12, wherein
the second stud bump includes a plurality of stud bumps, and
the second ball portion is joined to an uppermost layer of the plurality of stud bumps.

17. The semiconductor device according to claim 12, further comprising:
a fifth pad; and
a fifth bonding wire provided on the fifth pad with a fifth stud bump in between, wherein
the first, second, and third pads are arranged in a first direction,
the second bonding wire extends in a second direction that intersects the first direction,
the fourth pad is provided relative to the second pad in a third direction different from the first direction and the second direction,
the fifth bonding wire includes a fifth ball portion and a fifth wire portion, the fifth ball portion being joined to the fifth stud bump, the fifth wire portion extending from the fifth ball portion, and
a height of the fifth ball portion is higher than a height of the second ball portion.

18. The semiconductor device according to claim 12, wherein a material of the second stud bump is different from a material of the second bonding wire provided on the second stud bump.

19. A semiconductor device manufacturing method comprising:
forming a first pad, a second pad, and a third pad on a semiconductor chip;
forming a second bump on the second pad;
forming a first wire on the first pad by ball bonding; and
forming a second wire on the second bump by ball bonding after the first wire is formed.

20. The semiconductor device manufacturing method according to claim 19, wherein the forming of the second bump includes forming a stud bump by wire bonding.
